(19) United States
(12) Patent Application Publication
(10) Pub. No.: US 2007/0176255 A1
(43) Pub. Date: Aug. 2, 2007

(54) Integrated circuit arrangement

(76) Inventors: Franz Kreupl, Muenchen (DE); Georg Erhard Eggers, Muenchen (DE); Herbert Benzinger, Muenchen (DE); Ingo Bormann, Muenchen (DE); Martin Schnell, Worblingen (DE)

Correspondence Address: SLATER & MATSIL LLP, 17950 PRESTON ROAD, SUITE 1000, DALLAS, TX, 75252, US

(21) Appl. No.: 11/344,960

(22) Filed: Jan. 31, 2006

(51) Int. Cl. H01L 29/00

(52) U.S. Cl. 257/529

(57) ABSTRACT

An integrated circuit arrangement comprises at least one one-time programmable storage element, which can be electrically deactivated, having at least one electrically conductive or semi-conductive nanotube or at least one electrically conductive or semi-conductive nanowire.

### TECHNICAL FIELD

The invention relates to an integrated circuit arrangement.

### BACKGROUND

In many integrated circuits, for example, in many semiconductor integrated circuits, a permanent memory is required for storing binary data, which can be written once and which can be read an arbitrary number of times. An example of such an integrated circuit is a so-called programmable read only memory (PROM).

Furthermore, permanent storage cells are also required in a dynamic random access memory (DRAM) in order to store information about defect cells to be masked out, or in order to permanently match operation parameter.

One possibility of storing the information is using so-called laser fuses. Laser fuses are to be understood electrically conductive connections at the surface of the integrated circuit, which can be interrupted by means of a focused laser beam.

However, disadvantages of laser fuses may be seen in:

a) the remarkable size of the laser fuse circuits, the scaling down of which is limited by the wavelength of the laser that is used for melting the laser fuses; and

b) the fact that after molding the integrated circuit arrangement in a package, it is no longer possible to change the fuses; for this reason, it is not possible to mask out defects of cells, which occur after the molding, thereby reducing the yield.

FIG. 1 shows a laser fuse 100 comprising two electric terminals, a first electric terminal 102 and a second electric terminal 104. An electrically conductive laser fuse element 106 is arranged between and coupled to the first electric terminal 102 and the second electric terminal 104. The electrically conductive laser fuse element 106 is melted using a focused laser beam 108.

In order to overcome the above disadvantages of the laser fuses, so-called electronic fuses are examined, wherein the electrically conductive connection can be disconnected by means of a short high current pulse. However, the electronic fuses suffer from little reliability, since no material removal of the electrically conductive connection material to the outside of the integrated circuit is possible in a closed, i.e., packaged integrated circuit. For this reason, the material of the disconnected electrically conductive connection can step by step form an electrically conductive structure again. Thus, the information written by disconnecting the electrically conductive connection may be lost again.

### SUMMARY OF THE INVENTION

The integrated circuit arrangement according to a first aspect of the invention, comprises at least one one-time programmable storage element having at least one electrically conductive or semi-conductive nanotube or at least one electrically conductive or semi-conductive nanowire.

According to a second aspect of the invention, the integrated circuit arrangement comprises a first electronic terminal, a second electronic terminal and at least one one-time programmable storage element having at least one electrically conductive or semi-conductive nanotube or at least one electrically conductive or semi-conductive nanowire being coupled to the first electronic terminal and to the second electronic terminal.

According to a third aspect of the invention, the integrated circuit arrangement comprises a plurality of electronic terminals and a plurality of one-time programmable storage elements, each having at least one electrically conductive or semi-conductive nanotube or at least one electrically conductive or semi-conductive nanowire and being coupled to at least two of the electronic terminals.

A method for manufacturing an integrated circuit arrangement in accordance with a fourth aspect of the invention includes, providing a first electronic terminal, providing a second electronic terminal, providing at least one one-time programmable storage element having at least one electrically conductive or semi-conductive nanotube, or at least one electrically conductive or semi-conductive nanowire by coupling it to the first electronic terminal and to the second electronic terminal.

The method for programming an integrated circuit arrangement having a plurality of electronic terminals and a plurality of one-time programmable storage elements, each having at least one electrically conductive or semi-conductive nanotube or at least one electrically conductive or semi-conductive nanowire and being coupled to at least two of the electronic terminals, in accordance with a fifth aspect of the invention, comprises selectively deactivating one or a plurality of nanotubes or one or a plurality of nanowires.

The invention clearly achieves an electronic fuse element in an integrated circuit providing increased reliability.

These and other features of the invention will be better understood when taken in view of the following drawings and a detailed description.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a laser fuse element;

FIG. 2 illustrates an electronic fuse element in accordance with an embodiment of the present invention;

FIG. 3 illustrates an electronic fuse element in accordance with an embodiment of the present invention;

FIG. 4 illustrates an enlarged sectional view of a part of the electronic fuse element of FIG. 3;

FIG. 5A illustrates a top view of an integrated circuit arrangement in accordance with an embodiment of the present invention at a first time of its manufacturing;

FIG. 5B illustrates a top view of an integrated circuit arrangement in accordance with an embodiment of the present invention at a second time of its manufacturing;

FIG. 5C illustrates a top view of an integrated circuit arrangement in accordance with an embodiment of the present invention at a third time of its manufacturing; and

FIG. 6 illustrates an integrated circuit arrangement in accordance with an embodiment of the present invention.

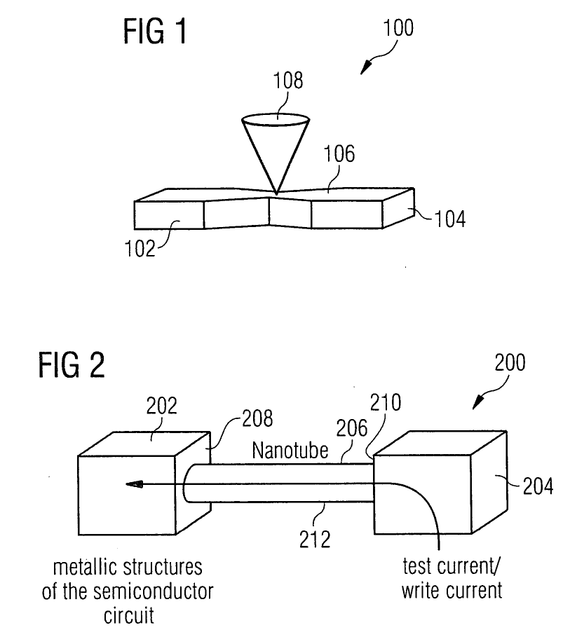

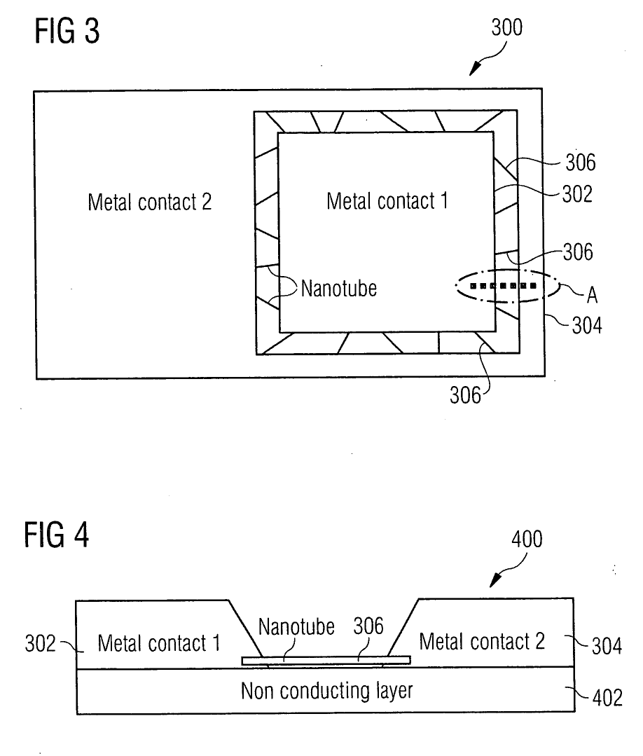

The following list of reference symbols can be used in conjunction with the figures:
100 laser fuse
102 first electric terminal
104 second electric terminal
106 electrically conductive laser fuse element
108 focused laser beam
200 electronic fuse element
202 first metallic terminal
204 second metallic terminal
206 carbon nanotube
208 first end portion carbon nanotube
210 second end portion carbon nanotube
212 programming current
300 electronic fuse element
302 first metal contact
304 second metal contact
306 carbon nanotube
400 cross-sectional view of region A of the electronic fuse element of FIG. 3
402 non-conducting layer
500 integrated circuit arrangement
502 substrate
504 electronic terminal
506 carbon nanotube
508 fuse element structure
600 dynamic semiconductor random access memory device
602 volatile memory cell
604 defect volatile memory cell
606 redundancy volatile memory cell
608 first arrow
610 second arrow
612 array of electronic fuses
614 global cell address

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In accordance with one aspect of the invention, the one-time programmable storage element is an electronic fuse element.

In accordance with another aspect of the invention, the at least one electrically conductive or semi-conductive nanotube is made of carbon. One or a plurality of carbon nanotubes may be provided in order to be programmed by means of electrically fusing them.

According to another embodiment of the invention, the at least one electrically conductive or semi-conductive nanowire is made of a material selected from:
Silicon;
Germanium;
at least one of the III-V-semiconductor BN, BP, BAs, AlN, AlP, AlAs, AlSb, GaN, GaP, GaAs, GaSb, InN, InP, InAs, InSb;
at least one of the II-VI-semiconductor ZnO, ZnS, ZnSe, ZnTe, CdS, CdSe, CdTe, HgS, HgSe, HgTe, BeS, BeSe, BeTe, MgS, MgSe;
at least one of the compositions GeS, GeSe, GeTe, SnS, SnSe, SnTe, PbO, PbS, PbSe, PbTe;
at least one of the compositions CuF, CuCl, CuBr, Cul, AgF, AgCl, AgBr, AgI;
wherein the above mentioned materials may be p-doped and n-doped.

One or a plurality of nanowires, e.g., made of one or a plurality of the above materials, may be provided in order to be programmed by electrically fusing them.

Furthermore, a fuse element programming unit for providing an electrical current to the at least one fuse element for programming the at least one fuse element may be provided. The fuse element programming unit may comprise one or a plurality of conducting tracks and, optionally, in addition, one or a plurality of energy sources, e.g., one or a plurality of current sources.

One embodiment of the method for manufacturing an integrated circuit arrangement, comprises providing the first electronic terminal comprises arranging the first electronic terminal on a substrate. Alternatively or in addition to this embodiment of the invention, the second electronic terminal may be arranged on a substrate.

The nanotube(s) may be deposited or grown on the substrate, e.g., by depositing the nanotube(s) out of the liquid phase.

Before depositing the nanotube(s) or the nanowire(s) on the substrate, the surface of the substrate may be sensitized, thereby further improving the bonding of them to the surface of the substrate. Silane groups may be used for sensitizing the surface of the substrate.

According to another aspect of the invention, non-desired nanotubes or nanowires may be removed by means of etching.

One embodiment of the method for programming an integrated circuit arrangement, comprises selectively deactivating one or a plurality of nanotubes or one or a plurality of nanowires comprising selectively destroying one or a plurality of nanotubes or one or a plurality of nanowires.

The invention is particularly suitable for the application in a memory circuit, e.g., a volatile memory circuit (e.g., a dynamic random access memory (DRAM), alternatively a non-volatile memory circuit. In accordance with this embodiment of the invention, the non-volatile memory circuit may be one selected from the group of:
a flash non-volatile memory circuit;
a ferroelectric random access memory (FeRAM) non-volatile memory circuit;
a magnet random access memory (MRAM) non-volatile memory circuit;
a phase change memory (PCM) non-volatile memory circuit;
a conductive bridging random access memory (CBRAM) non-volatile memory circuit; and
an organic random access memory (ORAM) non-volatile memory circuit.

It is to be noted that, although the embodiment of the invention will now be described with respect to DRAM volatile memory cell array comprising a plurality of DRAM cells, the invention is applicable to any suitable integrated circuit, e.g., clearly as a one-time programmable read only memory.

FIG. 2 shows an electronic fuse element 200, in accordance with an embodiment of the present invention.

The electronic fuse element 200, which is provided on a surface of a substrate (not shown in FIG. 2), comprises a first metallic terminal 202 (e.g., made of copper or aluminium), according to an exemplary embodiment of the invention, a part of a metallic structure of a semiconductor circuit, and a second metallic terminal 204 (e.g., made of copper or aluminium), according to an exemplary embodiment of the invention a terminal for providing an electric programming current (fuse current) and/or an electric read current.

At least one carbon nanotube 206 (e.g., a single wall carbon nanotube or a multi-wall carbon nanotube, wherein the carbon nanotube may be doped or undoped) is arranged between the first metallic terminal 202 and the second metallic terminal 204. A first end portion 208 of the carbon nanotube 206 is mechanically and electrically coupled to the first metallic terminal 202. A second end portion 210 of the carbon nanotube 206 is mechanically and electrically coupled to the second metallic terminal 204.

A programming current 212 for melting the carbon nanotube 206 is provided by a current source and is guided through the second metallic terminal 204 and through the carbon nanotube 206 to the first metallic terminal 202, thereby heating and melting the carbon nanotube 206, if desired. Furthermore, if it is to be determined as to whether the carbon nanotube 206 is deactivated, e.g., destroyed, a read current is provided by the current source and is guided through the second metallic terminal 204 and, if activated, through the carbon nanotube 206 to the first metallic terminal 202, where the resulting current is sensed and the resistance of the connection is determined, thereby determining as to whether the carbon nanotube 206 is deactivated (non-conducting) or active (metallically conducting or semi-conducting).

FIG. 3 shows an electronic fuse element 300 in accordance with another embodiment of the present invention.

The electronic fuse element 300, which is provided on a surface of a substrate, according to this exemplary embodiment of the invention a non-conducting layer 402 (see cross-sectional view 400 of region A of the electronic fuse element 300 of FIG. 3 (see FIG. 4), comprises a first metal contact 302 (e.g., made of copper or aluminium) and a second metal contact 304 (e.g., made of copper or aluminium), wherein the second metal contact 304 fully surrounds the first metal contact 302.

According to this exemplary embodiment of the invention, a plurality of carbon nanotubes 306 (e.g., single wall carbon nanotubes or multi-wall carbon nanotubes, wherein the carbon nanotubes may be doped or undoped), in an alternative embodiment of the invention a plurality of silicon nanowires, is arranged between the first metal contact 302 and the second metal contact 304. A respective first end portion of the carbon nanotubes 306 or nanowires is mechanically and electrically coupled to the first metal contact 302. A respective second end portion of the carbon nanotubes 306 or nanowires is mechanically and electrically coupled to the second metal contact 304.

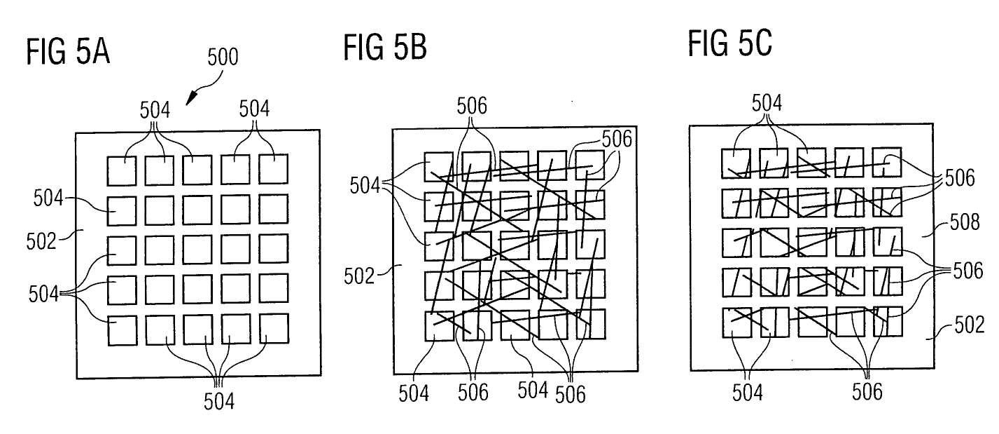

FIGS. 5A to 5C show a method for producing the electronic fuse elements in accordance with an embodiment of the present invention.

FIG. 5A shows a top view of an integrated circuit arrangement 500 in accordance with an embodiment of the present invention at a first time of its manufacturing,

The integrated circuit arrangement 500 comprises a plurality of electronic terminals 504, which are arranged on a substrate 502 in a matrix of rows and columns although they may be arranged in a different arrangement in alternative embodiments, e.g., in a hexagonal arrangement. The electronic terminals 504 are spaced apart from each other and, since the surface of the substrate is electrically isolating, they are also electrically isolated from each other.

It should be mentioned that the nanotube fuses or one-time-programming (OTP) storage elements can be provided with the carbon nanotubes in a front end of line (FEOL) process or in a back end of line (BEOL) process.

In principal, carbon nanotubes 506 are deposited on or at pre-manufactured structures (see FIG. 5B), e.g., on or at the electronic terminals 502, in a random manner. This may be accomplished by means of growing the carbon nanotubes 506 onto the surface of a wafer or by means of deposition out of the liquid phase, during which the carbon nanotubes 506 are formed and can be suspended in a liquid, thereby clearly forming a CNT suspension. This can be realized as described in M. J. O'Connell et. al, “Band Gap Fluoroscence from Individual Single-Walled Carbon Nanotubes,” SCIENCE, Volume 297, pages 593 to 596, July 2002, which is herewith fully incorporated by reference. In an alternative embodiment of the invention, the CNT suspension may be formed according to the method described in L. Jiang et. al., “Production of aqueous colloidal dispersions of carbon nanotubes,” Journal of Colloid and Interface Science, Number 260, pages 89 to 94, 2003, which is herewith fully incorporated by reference. In a further alternative embodiment of the invention, the CNT suspension may be formed according to the method described in Jie Liu et. al., “Fullerene Pipes,” SCIENCE, Volume 280, pages 1253 to 1256, May 1998, which is herewith fully incorporated by reference.

The density of the tubes may be influenced and controlled by controlling the growth or the way of the application of the suspension.

According to one exemplary embodiment of the invention, the surface of the substrate can be sensitized using silane groups in order to achieve a controlled (at predetermined positions preferred) deposition of the carbon nanotubes 506. However, this is not necessary in accordance with the exemplary embodiments of the invention.

The carbon nanotubes 506 are coupled to the electronic terminals 502 e.g., by means of van der Waals force.

After the carbon nanotubes 506 have been deposited, the desired pattern matrix is defined by means of photo resist structuring.

Existing carbon nanotube bridges (in other words carbon nanotube connections) between electronic terminals 502, which are not desired, are removed by means of a short oxygen dry etch process or by means of a short hydrogen dry etch process in a very easy manner.

The remaining carbon nanotube structure forms the electronic fuse element structure 508 (see FIG. 5C). The carbon nanotubes 506 of the remaining carbon nanotube structure can be electrically deactivated or destroyed by means of a voltage pulse or a current pulse. The yield depends on the density of the carbon nanotubes 506 in the carbon nanotube structure and on the applied pulse voltage.

According to an exemplary embodiment of the invention, an electrical current of approximately 20 μA to 30 μA is provided for each carbon nanotube and is flowing through the respective carbon nanotube in order to deactivate them. Alternatively, the occurring electrical fields in the respective carbon nanotube should be greater than approximately 1 Volt/100 nm (approximately 10⁵ V/cm).

In alternative embodiments of the invention any method that is suitable for deactivating the carbon nanotubes, generally speaking, the nanotubes or nanowires, can be used, e.g., the methods for providing electrical breakdown of single wall carbon nanotubes, which are described in R. V. Seidel et. al., “Bias dependence and electrical breakdown of small diameter single-walled carbon nanotubes,” Journal of Applied Physics, Volume 96, Number 11, pages 6694 to 6699, December 2004, which is herewith fully incorporated by reference.

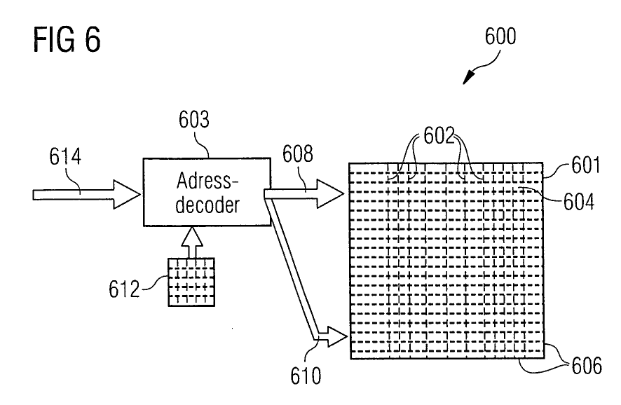

FIG. 6 shows an exemplary embodiment of the invention, in which the one-time programmable nanotubes or nanowires as they are described above, are provided in a dynamic semiconductor random access memory (DRAM) device 600.

The DRAM 600 comprises, inter alia, an array 601 of a plurality of volatile memory cells 602, each memory cell having, for example, a select transistor, a capacitor and a resistor. The array 601 further has redundancy volatile memory cells 606, which are only used in case a “regular” volatile memory cell 602 within the array 601 is defect and needs to be replaced by a redundancy volatile memory cell 606 of a redundancy region within the array 601.

The volatile memory cells 602 are arranged in rows and columns within the array 601. Furthermore, an address decoder 603 is provided which determines the address of the respective volatile memory cell 602 within the array 601 upon receipt of a global cell address 614. The address decoder 603 further determines, upon a request to read a respective volatile memory cell 602, whether the requested volatile memory cell 602 in the array 601 is marked as being a defect volatile memory cell 604 or not.

If the determined volatile memory cell 602 is not marked as defect, the content of the respective volatile memory cell 602 is read (indicated in FIG. 6 by means of a first arrow 608). However, if the determined volatile memory cell 602 is marked as defect, the respective redundancy volatile memory cell 605 is determined, which replaces the determined defect volatile memory cell 602, and the content of the respective redundancy volatile memory cell 605 is read (indicated in FIG. 6 by means of a second arrow 610).

The information as to whether a respective volatile memory cell 602 is defect or not, generally speaking, the information about defect regions within the array 601, is, according to this exemplary embodiment of the invention, stored in a permanent, one time programmable (OTP) memory, that is formed by means of an array 612 of, e.g., one time programmable (OTP), electronic fuses as they are described above.

However, it should be noted, that the invention can be provided in any kind of memory arrangement, e.g., a non-volatile memory arrangement, for example one of the following types of non-volatile memory arrangements, e.g., to store information about defect memory cells:
a flash non-volatile memory circuit,
a ferroelectric random access memory (FeRAM) non-volatile memory circuit,
a magnet random access memory (MRAM) non-volatile memory circuit,
a phase change memory (PCM) non-volatile memory circuit,
a conductive bridging random access memory (CBRAM) non-volatile memory circuit,
an organic random access memory (ORAM) non-volatile memory circuit.

Furthermore, the invention can also be used as a programmable read only memory (PROM).

One aspect of the invention may clearly be seen in the provision of a write-once storage element comprising at least one deactivatable nanotube or at least one deactivatable nanowire.

In other words, one aspect of the invention may be seen in a nanotube or nanowire interconnection between two metal electrodes per memory cell. The nanotube or nanowire acts as a fuse-like resistor. The resistance can e.g., be changed once by applying a current pulse destroying the nanotube or nanowire so that the resistance of the interconnection is increased.

As an example, it is assumed that one nanotube (e.g., a carbon nanotube) can carry up to 24 μA and that the resistance of a nanotube varies between 7 KOhm and 10 Mohm, depending on the type of nanotube that is used. In order to provide a rough estimation, it is further assumed that there are 100 nanotubes provided, each nanotube having a resistance of 7 KOhm, connecting two metal electrodes (contacts) of an unblown electronic fuse, wherein the resistance of the entirety of unblown nanotubes, which are connected in parallel, is 70 Ohm. The current required to destroy the nanotubes then should be greater than 100*24 μA=2.4 mA. This would require a voltage of approximately 24 μA*7 Kohm=0.17 V. After the nanotubes have been destroyed, the resistance of the (clearly no longer existing) interconnection between the metal contacts should be very high. The resistance can be measured by applying a small measurement current through the two metal contacts and the interconnection formed by the nanotubes.

According to one aspect of the invention, the coding of the storage elements (deactivated and remained activated nanotubes or nanowires) is not resettable, but the coding can be provided even after the molding of the integrated circuit arrangement.

Thus, if the coding is selected in a suitable manner, it is possible to mask out cells, e.g., storage cells, even if it is recognized that they are defect only after the completion of the manufacturing of the respective component

Various aspects of the invention provide, inter alia, the following advantages:
Carbon nanotubes have a high conductivity, which provides a reliable reading of the memory cells formed by the carbon nanotubes.
There is only a small amount of distribution of crucial parameters like the conductivity of destruction threshold due to the atomic order. Since the remaining resistance results mainly from the interface of a respective nanotube and the surrounding circuit, the length of the respective nanotube is not important.
The high conductivity of the nanotubes is an effect of the perfect grid arrangement of the carbon atoms. If this perfect grid arrangement is destroyed by means of a current pulse, the conductivity of the nanotubes changes dramatically. This change remains even if the carbon nanotubes remain at the place of the carbon nanotubes in a disordered manner.
A scaling down of the fuse structures of multiple magnitudes is possible due to the diameter of the carbon nanotubes, which is in a range of approximately 10 nm.
A nanotube or nanowire fuse can be implemented in a metal layer, which is one of the top layers of a semiconductor device, so that it is possible to implement such fuses in a relatively easy way.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed is:

1. An integrated circuit arrangement comprising at least one one-time programmable storage element, which can be electrically deactivated, having at least one electrically conductive or semi-conductive nanotube or at least one electrically conductive or semi-conductive nanowire.

2. The integrated circuit arrangement of claim 1, wherein the one-time programmable storage element comprises an electronic fuse element.

3. The integrated circuit arrangement of claim 1, wherein the at least one electrically conductive or semi-conductive nanotube is made of carbon.

4. The integrated circuit arrangement of claim 1, wherein the at least one electrically conductive or semi-conductive nanowire comprises a material selected from the group consisting of:
silicon;
germanium;
at least one of the III-V-semiconductor BN, BP, BAs, AlN, AlP, AlAs, AlSb, GaN, GaP, GaAs, GaSb, InN, InP, InAs, InSb;
at least one of the II-VI-semiconductor ZnO, ZnS, ZnSe, ZnTe, CdS, CdSe, CdTe, HgS, HgSe, HgTe, BeS, BeSe, BeTe, MgS, MgSe;
at least one of the compositions GeS, GeSe, GeTe, SnS, SnSe, SnTe, PbO, PbS, PbSe, PbTe; and
at least one of the compositions CuF, CuCl, CuBr,CuI, AgF, AgCl, AgBr, AgI.

5. The integrated circuit arrangement of claim 1, further comprising a storage element programming unit for providing an electrical current to the at least one fuse element for programming the at least one storage element.

6. An integrated circuit arrangement comprising:
a first electronic terminal;
a second electronic terminal;
at least one one-time programmable storage element, which can be electrically deactivated, having at least one electrically conductive or semi-conductive nanotube or at least one electrically conductive or semi-conductive nanowire being coupled to the first electronic terminal and to the second electronic terminal.

7. The integrated circuit arrangement of claim 6, wherein the one-time programmable storage element comprises an electronic fuse element.

8. The integrated circuit arrangement of claim 6, wherein the at least one electrically conductive or semi-conductive nanotube is made of carbon.

9. The integrated circuit arrangement of claim 6, wherein the at least one electrically conductive or semi-conductive nanowire comprises a material selected from the group consisting of:
silicon;
germanium;
at least one of the III-V-semiconductor BN, BP, BAs, AIN, AIP, AlAs, AlSb, GaN, GaP, GaAs, GaSb, InN, InP, InAs, InSb;
at least one of the II-VI-semiconductor ZnO, ZnS, ZnSe, ZnTe, CdS, CdSe, CdTe, HgS, HgSe, HgTe, BeS, BeSe, BeTe, MgS, MgSe;
at least one of the compositions GeS, GeSe, GeTe, SnS, SnSe, SnTe, PbO, PbS, PbSe, PbTe; and
at least one of the compositions CuF, CuCl, CuBr,CuI, AgF, AgCl, AgBr, AgI.

10. The integrated circuit arrangement of claim 6, further comprising a storage element programming unit for providing an electrical current to the at least one fuse element for programming the at least one storage element.

11. An integrated circuit arrangement comprising:
a plurality of electronic terminals; and
a plurality of one-time programmable storage elements that can be electrically deactivated, each one-time programmable storage element having at least one electrically conductive or semi-conductive nanotube or at least one electrically conductive or semi-conductive nanowire and being coupled to at least two of the electronic terminals.

12. The integrated circuit arrangement of claim 11, wherein the one-time programmable storage element comprises an electronic fuse element.

13. The integrated circuit arrangement of claim 11, wherein the at least one electrically conductive or semi-conductive nanotube is made of carbon.

14. The integrated circuit arrangement of claim 11, wherein the at least one electrically conductive or semi-conductive nanowire comprises a material selected from the group consisting of:
silicon;
germanium;
at least one of the III-V-semiconductor BN, BP, BAs, AIN, AIP, AlAs, AlSb, GaN, GaP, GaAs, GaSb, InN, InP, InAs, InSb;
at least one of the II-VI-semiconductor ZnO, ZnS, ZnSe, ZnTe, CdS, CdSe, CdTe, HgS, HgSe, HgTe, BeS, BeSe, BeTe, MgS, MgSe;
at least one of the compositions GeS, GeSe, GeTe, SnS, SnSe, SnTe, PbO, PbS, PbSe,PbTe;and
at least one of the compositions CuF, CuCl, CuBr,CuI, AgF, AgCl, AgBr, AgI.

15. The integrated circuit arrangement of claim 11, further comprising a storage element programming unit for providing an electrical current to the at least one fuse element for programming the at least one storage element.

16. A method for manufacturing an integrated circuit arrangement, the method comprising:
providing a first electronic terminal;
providing a second electronic terminal; and
providing at least one electronic one-time programmable storage element that can be electrically deactivated, the at least one electronic one-time programmable storage element having at least one electrically conductive or semi-conductive nanotube or at least one electrically conductive or semi-conductive nanowire coupled to the first electronic terminal and to the second electronic terminal.

17. The method of claim 16, wherein providing the first electronic terminal comprises arranging the first electronic terminal on a substrate.

18. The method of claim 17, wherein providing the second electronic terminal comprises arranging the second electronic terminal on a substrate.

19. The method of claim 17, wherein providing at least one electronic one-time programmable storage element comprises depositing or growing the nanotube on the substrate.

20. The method of claim 19, wherein depositing the nanotube on the substrate comprises depositing the nanotube out of the liquid phase.

21. The method of claim 19, further comprising sensitizing the surface of the substrate before depositing the nanotube on the substrate.

22. The method of claim 21, wherein sensitizing the surface of the substrate comprises sensitizing the surface of the substrate using silane.

23. The method of claim 19, further comprising removing undesired nanotubes or nanowires by means of etching.

24. A method for programming an integrated circuit arrangement having a plurality of electronic terminals, and a plurality of electronic one-time programmable storage element that can be electrically deactivated, each electronic one-time programmable storage element having at least one electrically conductive or semi-conductive nanotube or at least one electrically conductive or semi-conductive nanowire and being coupled to at least two of the electronic terminals, the method comprising selectively deactivating one or a plurality of nanotubes or one or a plurality of nanowires.

25. The method of claim 24, wherein selectively deactivating one or a plurality of nanotubes or one or a plurality of nanowires comprises selectively destroying one or a plurality of nanotubes or one or a plurality of nanowires.
